(19) United States
(12) Patent Application Publication
(10) Pub. No.: US 2013/0215077 A1
(43) Pub. Date: Aug. 22, 2013

(54) TOUCH CONTROL DISPLAY APPARATUS AND MANUFACTURING METHOD THEREOF

(71) Applicants: INNOCOM TECHNOLOGY (SHENZHEN) CO., LTD, (US); Innolux Corporation, (US)

(72) Inventors: Kung-Chieh HUANG, Chu-Nan (TW); Mei-Zhen ZHANG, Chu-Nan (TW); Pei-Chun HSIEH, Chu-Nan (TW)

(73) Assignees: INNOLUX CORPORATION, Chu-Nan (TW); INNOCOM TECHNOLOGY (SHENZHEN) CO., LTD, Shenzhen City (CN)

(21) Appl. No.: 13/761,795

(22) Filed: Feb. 7, 2013

(30) Foreign Application Priority Data
Feb. 20, 2012 (TW) 101105529

(51) Int. Cl. H01H 11/00; G06F 3/044; H03K 17/96

(52) U.S. Cl. CPC H01H 11/00; H03K 17/9618; G06F 3/044
USPC 345/174; 200/5 A; 29/622

(57) ABSTRACT

A touch control display apparatus according to the disclosure comprises a display panel and a touch panel. The display panel has a display surface. The touch panel is disposed on the display surface side and comprises a first film, a second film, and a plurality of sensing electrodes. The second film is disposed parallel with the first film. The sensing electrodes are disposed on at least one of the first film and the second film. The first film and the second film each are at least made of a birefringence material and have a fast-axis direction, and the fast-axis directions of the first and second films have an included angle substantially between 70 degrees and 110 degrees. A manufacturing method of the touch control display apparatus is also disclosed.

### CROSS REFERENCE TO RELATED APPLICATIONS

This Non-provisional application claims priority under 35 U.S.C. §119(a) on Patent Application No(s). 101105529 filed in Taiwan, Republic of China on Feb. 20, 2012, the entire contents of which are hereby incorporated by reference.

### BACKGROUND OF THE INVENTION

1. Field of Invention

The invention relates to a display apparatus and a manufacturing method thereof and, in particular, to a touch control display apparatus and a manufacturing method thereof.

2. Related Art

Various touch control display apparatuses have become indispensible articles for daily use. With the increasingly keen marketing competition and strict consumers' demands, the display quality of the touch control display apparatus is also an important design factor for the industry

In the conventional art, the touch panel includes an upper PET (polyethylene terephthalate) film and a lower PET film, both of which are manufactured by a roll-to-roll method. However, the PET film manufactured by the roll-to-roll method will be configured with an optical anisotropic feature, which affects the velocity of the light. Therefore, either the incident light or the light emitted from the LCD panel will be given a phase retardation when passing through the PET film, thereby causing the light emitted from the linear polarizer a phase difference.

Because the light emitted from the touch display panel has phase difference, constructive interference or destructive interference will occur when the light further passes through a linear polarizer of a pair of sunglasses worn by a user to view an image, thereby causing the problem of rainbow fringes.

In order to prevent the rainbow fringes, the PET film can be otherwise manufactured by a cell-cast manufacturing process. However, the cell-cast manufacturing process needs higher cost, and thus the cost of the touch display panel is also increased.

### SUMMARY OF THE INVENTION

In view of the foregoing, an objective of the disclosure is to provide a touch control display apparatus and a manufactured method thereof that can prevent the rainbow fringes while reducing the cost.

To achieve the above objective, a touch panel according to the disclosure comprises a first film, a second film, and a plurality of sensing electrodes. The second film is disposed parallel with the first film. The sensing electrodes are disposed on at least one of the first film and the second film, wherein the first film and the second film each are at least made of a birefringence material and have a fast-axis direction, and the fast-axis directions of the first and second films have an included angle substantially between 70 degrees and 110 degrees.

To achieve the above objective, a touch control display apparatus according to the disclosure comprises a display panel and a touch panel. The display panel has a display surface. The touch panel is disposed on the display surface side and comprises a first film, a second film, and a plurality of sensing electrodes. The second film is disposed parallel with the first film. The sensing electrodes are disposed on at least one of the first film and the second film, wherein the first film and the second film each are at least made of a birefringence material and have a fast-axis direction, and the fast-axis directions of the first and second films have an included angle substantially between 70 degrees and 110 degrees.

In one embodiment, the sensing electrodes are disposed on the first film. Otherwise, the sensing electrodes can be disposed on a surface of the first film, the opposite surfaces of the first film, the first and second films, the opposite surfaces of the first and second films, the surfaces on the same side of the first and second films, or the surfaces on the opposite sides of the first and second films.

In one embodiment, the included angle is 90 degrees substantially.

In one embodiment, the touch control display apparatus further comprises a first optical polarizing component and a second optical polarizing component. The first optical polarizing component is disposed on a side of the touch panel far from the display panel. The second optical polarizing component is disposed between the touch panel and the display panel. Each of the first and second optical polarizing components is a circular polarizing component. The first optical polarizing component or the second optical polarizing component includes a linear polarizer and a quarter-wave plate.

In one embodiment, the material of the first and second films is PET.

To achieve the above objective, a manufacturing method of a touch control display apparatus according to the disclosure comprises the steps of: providing a first film and a second film, each of which is at least made of a birefringence material and has a fast-axis direction, wherein the fast-axis directions of the first and second films are different from each other; and disposing a plurality of sensing electrodes on at least one of the first film and the second film.

In one embodiment, the step of providing the first and second films further comprises the steps of: treating a plastic material by a roll-to-roll process to form a plastic film, which is at least made of a birefringence material; cutting the plastic film along a first direction to form the first film; and cutting the plastic film along a second direction to form the second film, wherein the first direction and the second direction have an included angel substantially between 70 degrees and 110 degrees.

In one embodiment, the step of forming the first and second films further comprises the steps of: cutting the plastic film along the first direction to form the first film by a cutting device; and rotating the cutting device to cut the plastic film along the second direction to form the second film.

In one embodiment, the step of forming the first and second films further comprises the steps of: cutting the plastic film along the first direction to form the first film by a first cutting device; and cutting the plastic film along the second direction to form the second film by a second cutting device, wherein the angle difference of the first and second cutting devices is substantially equal to the included angle of the first and second directions.

As mentioned above, the manufacturing method of the touch control display apparatus of the disclosure is to provide a first film and a second film whose fast-axis directions are different from each other to prevent the rainbow fringes. Therefore, the optical film of the touch panel of the disclosure can be manufactured by the roll-to-roll process with the lower cost. Besides, if the fast-axis directions of the first and second films are substantially perpendicular to each other, the light will not be given the phase retardation when passing through the first and second films. In other words, the light is not caused phase difference when emitted from the touch control display apparatus of the disclosure, thereby preventing the rainbow fringes.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a flow chart of a manufacturing method of a touch control display apparatus of a preferred embodiment of the disclosure; and

FIGS. 2A to 2E are schematic diagrams of the manufacturing process of the touch control display apparatus of the disclosure.

### DETAILED DESCRIPTION OF THE INVENTION

The present invention will be apparent from the following detailed description, which proceeds with reference to the accompanying drawings, wherein the same references relate to the same elements.

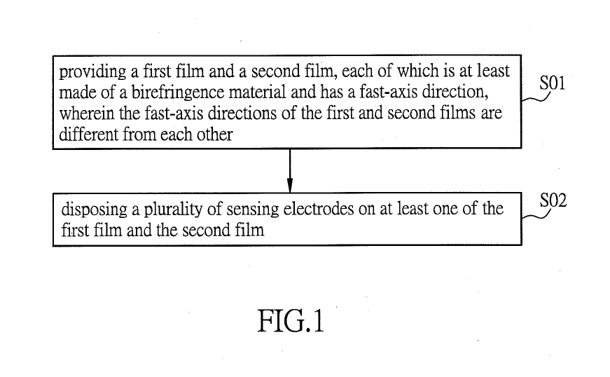

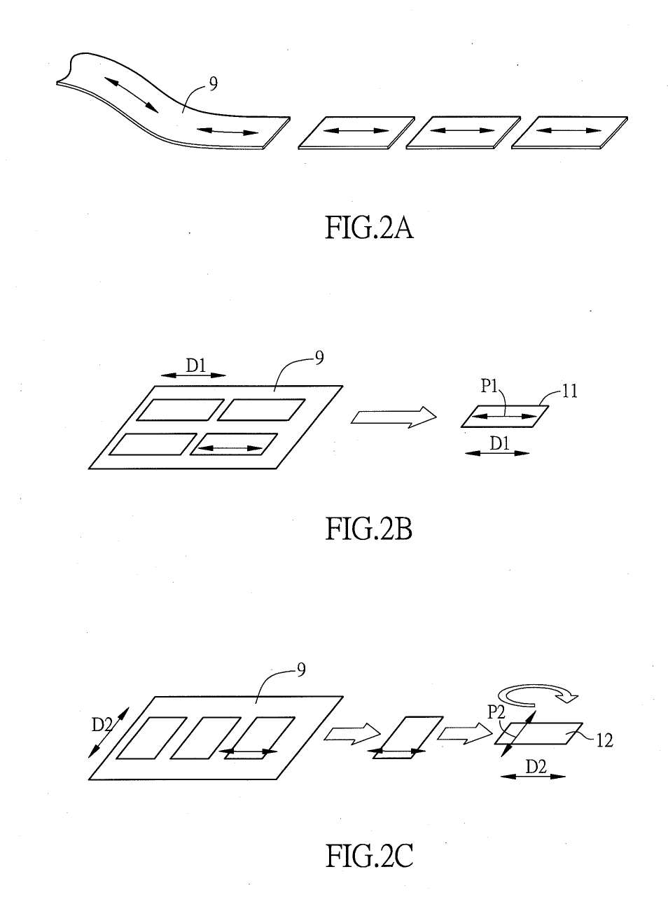

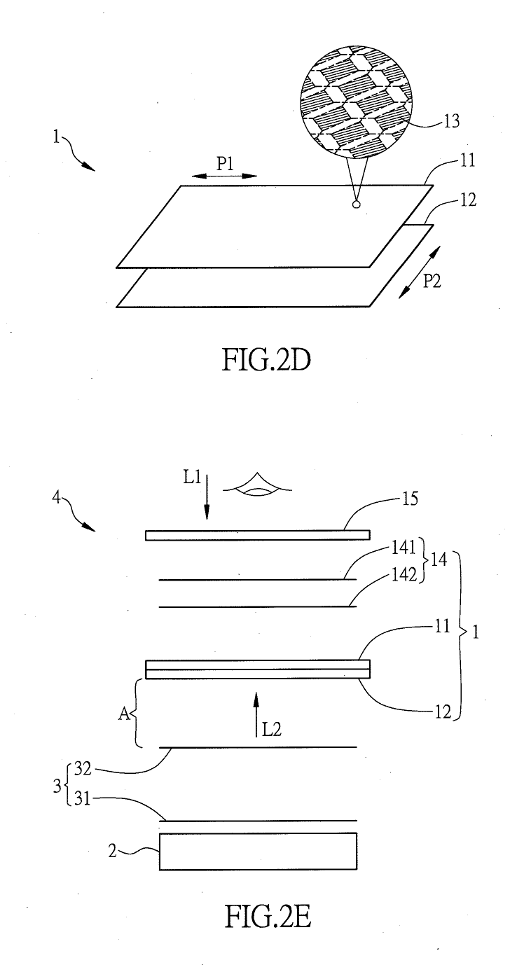

FIG. 1 is a flow chart of a manufacturing method of a touch control display apparatus of a preferred embodiment of the disclosure, and FIGS. 2A to 2E are schematic diagrams of the manufacturing process of the touch control display apparatus. The manufacturing method of the optical film of the embodiment includes the steps S01 and S02.

As shown in FIG. 1 and FIGS. 2A to 2E, the step S01 is to provide a first film 11 and a second film 12, which are each made of a birefringence material at least and have fast-axis directions P1 and P2 respectively. The fast-axis directions P1 and P2 of the first and second films 11 and 12 are different from each other.

As shown in FIGS. 1 and 2A, in the step S01, a plastic material is treated by a roll-to-roll process to form a plastic film 9 for providing the first film and the second film. The plastic film 9 is at least made of a birefringence material and has a fast-axis direction. The roll-to-roll process is conducted by a plurality of rollers in the embodiment, and the plastic film 9 becomes an anisotropic optical film due to the roll-to-roll process. The material of the plastic film 9 can be PET (Polyethylene terephthalate) for example, and that means the material of the first and second films 11 and 12 is PET. Then, the plastic film 9 needs to be cut into pieces with proper size.

As shown in FIGS. 1, 2B and 2C, the pieces of the plastic film 9 can be further cut according to the required size, wherein the plastic film 9 is cut along a first direction D1 to form the first film 11, and cut along a second direction D2 to form the second film 12. In the embodiment, the first direction D1 and the second direction D2 have an included angel substantially between 70 degrees and 110 degrees. The longitudinal direction D1 of the first film 11 is parallel with or perpendicular to the fast-axis direction P1 preferably, but not for limiting the scope of the disclosure, and for example here, the longitudinal direction D1 and the fast-axis direction P1 of the first film 11 are parallel with each other. Besides, the longitudinal direction D2 and the fast-axis direction P2 of the second film 12 are perpendicular to each other, for example. The second film 12 is rotated for 90 degrees for example to have the fast-axis direction P2 perpendicular to the longitudinal direction D2.

As shown in FIGS. 2B and 2C, when the first film 11 and the second film 12 are arranged along the longitudinal directions D1 and D2 respectively, the fast-axis directions P1 and P2 of the first and second films 12 substantially have an included angle between 70 degrees and 110 degrees. In this embodiment, the included angle is, for example but not limited to, 90 degrees. If the fast-axis directions P1 and P2 of the first and second films 11 and 12 are substantially perpendicular to each other, the light will not be given phase retardation when passing through the first and second films 11 and 12. In other words, the phase difference will not occur when the external light passes through the first and second films 11 and 12. Accordingly, the first film 11 and the second film 12 can be manufactured by the roll-to-roll process to reduce the cost.

To be noted, the plastic film 9 can be cut by a cutting device (not shown) along the first direction D1 to form at least one first film 11, and then the cutting device is rotated to cut the plastic film 9 along the second direction D2 to form at least one second film 12. In other words, the first and second films 11 and 12 are manufactured by the same cutting device.

Otherwise, the plastic film 9 is cut along the first direction D1 by a first cutting device (not shown) to form the first film 11, and the plastic film 9 is cut along the second direction D2 by a second cutting device (not shown) to form the second film 12. The angle difference of the first and second cutting devices is substantially equal to the included angle of the first and second directions D1 and D2. In other words, the first and second films 11 and 12 are manufactured by different cutting devices.

Afterwards, as shown in FIGS. 1 and 2D, the step S02 is to dispose a plurality of sensing electrodes 13 on at least one of the first film 11 and the second film 12 to form a touch panel 1. To be noted, the sensing electrode 13 is not limited in pattern in the embodiment. The sensing electrodes 13 can be disposed on the first film 11, such as on a surface of the first film 11, or on the opposite surfaces of the first film 11. Otherwise, the sensing electrodes 13 can be disposed on the first and second films 11 and 12, such as on the opposite surfaces of the first and second films 11 and 12, on the surfaces on the same side of the first and second films 11 and 12, or on the surfaces on the opposite sides of the first and second films 11 and 12. Herein, the sensing electrodes 13 are instanced as disposed on the first film 11. The sensing electrode 13 is made of ITO (Indium Tin Oxide) for example.

FIG. 2E is a schematic diagram of a touch control display apparatus 4 of a preferred embodiment of the disclosure. The manufacturing method of the touch control display apparatus 4 can further include the steps of: disposing a first optical polarizing component 14 on a side of the touch panel 1 far from the display panel 2; and disposing a second optical polarizing component 3 between the touch panel 1 and the display panel 2. The display panel 2 can be an LCD (liquid crystal display) panel or an OLED (organic light-emitting diode) display panel, and is instanced as an LCD panel in the embodiment.

The first optical polarizing component 14 and the second optical polarizing component 3 each can be a circular polarizing component. In the embodiment, the first optical polarizing component 14 includes a linear polarizer 141 and a quarter-wave plate 142, and the second optical polarizing component 3 includes a linear polarizer 31 and a quarter-wave plate 32, for example. Besides, the touch panel 1 further includes a protective glass 15, which is disposed on the first optical polarizing component 14 for providing the protection function.

Accordingly, the linear polarizer 141 and the quarter-wave plate 142 are disposed between the first film 11 and the protective glass 15, and an air gap A is formed between the second film 12 and the quarter-wave plate 32. Thus, the ambient light L1 first passes through the linear polarizer 141 to become the linearly polarized light, and then passes through the quarter-wave plate 142 to become the circularly polarized light due to the phase retardation. Afterwards, the light passes through the first and second films 11 and 12, and is totally reflected off the second film 12 due to the difference of refractive index caused by the air gap A. Subsequently, the light passes through the quarter-wave plate 142 again to become the linearly polarized light, which however can not pass through the linear polarizer 141 because of the different polarized direction, providing the anti-reflection effect for the touch control display apparatus 4. Besides, the light passing through either the first film 11 or the second film 12 will not be given the phase retardation. In other words, the light passing through the first and second films 11 and 12 has no phase difference, thereby preventing the rainbow fringes.

To be noted, if the touch panel is composed of a substrate and a touch film, a film with different polarizing direction from the touch film can be added to prevent the rainbow fringes.

In summary, the manufacturing method of the touch control display apparatus of the disclosure is to provide a first film and a second film whose fast-axis directions are different from each other to prevent the rainbow fringes. Therefore, the optical film of the touch panel of the disclosure can be manufactured by the roll-to-roll process with the lower cost. Besides, if the fast-axis directions of the first and second films are substantially perpendicular to each other, the light will not be given the phase retardation when passing through the first and second films. In other words, the light is not caused phase difference when emitted from the touch control display apparatus of the disclosure, thereby preventing the rainbow fringes.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A touch panel, comprising:
a first film;
a second film disposed parallel with the first film; and
a plurality of sensing electrodes disposed on at least one of the first film and the second film, wherein the first film and the second film each are at least made of a birefringence material and have a fast-axis direction, and the fast-axis directions of the first and second films have an included angle substantially between 70 degrees and 110 degrees.

2. The touch panel as recited in claim 1, wherein the sensing electrodes are disposed on the first film.

3. The touch panel as recited in claim 2, wherein the sensing electrodes are disposed on a surface of the first film.

4. The touch panel as recited in claim 2, wherein the sensing electrodes are disposed on the opposite surfaces of the first film.

5. The touch panel as recited in claim 1, wherein the sensing electrodes are disposed on the first and second films.

6. The touch panel as recited in claim 5, wherein the sensing electrodes are disposed on the opposite surfaces of the first and second films.

7. The touch panel as recited in claim 5, wherein the sensing electrodes are disposed on the surfaces on the same side of the first and second films.

8. The touch panel as recited in claim 5, wherein the sensing electrodes are disposed on the surfaces on the opposite sides of the first and second films.

9. The touch panel as recited in claim 1, wherein the included angle is 90 degrees substantially.

10. A touch control display apparatus, comprising:
a display panel having a display surface; and
a touch panel disposed on the display surface side and comprising:
a first film;
a second film disposed parallel with the first film; and
a plurality of sensing electrodes disposed on at least one of the first film and the second film, wherein the first film and the second film each are at least made of a birefringence material and have a fast-axis direction, and the fast-axis directions of the first and second films have an included angle substantially between 70 degrees and 110 degrees.

11. The touch control display apparatus as recited in claim 10, wherein the included angle is 90 degrees substantially.

12. The touch control display apparatus as recited in claim 10, further comprising:
a first optical polarizing component disposed on a side of the touch panel far from the display panel; and
a second optical polarizing component disposed between the touch panel and the display panel.

13. The touch control display apparatus as recited in claim 12, wherein each of the first and second optical polarizing components is a circular polarizing component.

14. The touch control display apparatus as recited in claim 12, wherein the first optical polarizing component or the second optical polarizing component includes a linear polarizer and a quarter-wave plate.

15. A manufacturing method of a touch control display apparatus, comprising the steps of:
providing a first film and a second film, each of which is at least made of a birefringence material and has a fast-axis direction, wherein the fast-axis directions of the first and second films are different from each other; and
disposing a plurality of sensing electrodes on at least one of the first film and the second film.

16. The manufacturing method as recited in claim 15, wherein the step of providing the first and second films further comprises the steps of:
treating a plastic material by a roll-to-roll process to form a plastic film, which is at least made of a birefringence material;
cutting the plastic film along a first direction to form the first film; and
cutting the plastic film along a second direction to form the second film, wherein the first direction and the second direction have an included angel substantially between 70 degrees and 110 degrees.

17. The manufacturing method as recited in claim 16, wherein the step of forming the first and second films further comprises the steps of:
cutting the plastic film along the first direction to form the first film by a cutting device; and
rotating the cutting device to cut the plastic film along the second direction to form the second film.

18. The manufacturing method as recited in claim 16, wherein the step of forming the first and second films further comprises the steps of:
cutting the plastic film along the first direction to form the first film by a first cutting device; and
cutting the plastic film along the second direction to form the second film by a second cutting device, wherein the angle difference of the first and second cutting devices is substantially equal to the included angle of the first and second directions.

19. The manufacturing method as recited in claim 15, wherein the sensing electrodes are disposed on the first film.

20. The manufacturing method as recited in claim 15, wherein the sensing electrodes are disposed on the first film and the second film.
